(19) United States
(12) Patent Application Publication
(10) Pub. No.: US 2008/0076191 A1
(43) Pub. Date: Mar. 27, 2008

(54) GCIB smoothing of the contact level to improve PZT films

(75) Inventors: Lindsey Hall, Plano, TX (US); Sanjeev Aggarwal, Plano, TX (US); Satyavolu Srinivas Papa Rao, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/525,475

(22) Filed: Sep. 22, 2006

(51) Int. Cl. H01L 21/8242

(52) U.S. Cl. 438/3; 438/240; 438/396

(57) ABSTRACT

A ferroelectric capacitor stack is formed over a metal-dielectric interconnect layer. After forming the interconnect layer, the surface of the interconnect layer is treated with gas cluster ion beam (GCIB) processing. Prior to this processing, the surface typically includes metal recesses. The GCIB processing smoothes these recesses and provides a more level surface on which to form the ferroelectric capacitor stack. When the ferroelectric capacitor stack is formed on this leveled surface, leakage is reduced and yields increased as compared to the case where GCIB processing is not used.

### FIELD OF THE INVENTION

The present invention relates generally to the field of integrated circuit processing, and more particularly relates to a method of manufacturing FeRAM.

### BACKGROUND

The semiconductor industry has long faced a demand for small, portable personal devices. These devices include cellular phones, personal computing equipment, and personal sound systems, which are sought in continuously smaller sizes and with continuously lower power requirements. At the same time that smaller and more portable personal devices are sought, computational power and on-chip memory requirements are increasing. In light of these requirements, there has been a long-felt need for computational devices that have substantial memory and logic functions integrated within individual semiconductor chips. Preferably, the memory is configured such that if power is interrupted, as when a battery fails, the contents of the memory are retained. Memory that retains its content without a continuous supply of power is called non-volatile memory. Conventional non-volatile memory types include: electrically erasable programmable read only memory (EEPPROM) and flash EEPROM.

Ferroelectric random access memory (FeRAM) is a type of non-volatile memory that stores data in memory cells that include capacitors employing a ferroelectric material, such as SBT or PZT, as the dielectric. The non-volatility of FeRAM results from the bi-stable characteristic of ferroelectric materials. At least two types of ferroelectric memory cells are used, single capacitor memory cells and dual capacitor memory cells. The single capacitor memory cell (referred to as a 1T/1C or 1C memory cell) requires less silicon area and thereby increases the potential density of the memory array, but is less immune to noise and process variations. A 1C cell requires a voltage reference for determining a stored memory state. The dual capacitor memory cell (referred to as a 2T/2C or 2C memory cell) requires more silicon area and stores complementary signals allowing differential sampling of the stored information.

As illustrated in prior art FIG. 1, a 1T/1C FeRAM cell 10 includes a transistor 12 and a ferroelectric storage capacitor 14. The transistor 12 includes a gate 16, a source 18, and a drain 15. The storage capacitor 14 includes a bottom electrode 17, a top electrode 21, and a ferroelectric core. The drain 15 of the transistor 12 is connected to the bottom electrode 17 of the capacitor 14. The source 18 of the transistor 12 is connected to a bit line BL. The 1T/1C cell 10 is read by applying a signal to the gate 16 through a word line WL, switching on the transistor 12. This brings the bottom electrode 17 of the capacitor 14 into communication with the bit line BL. Then, though a drive line DL, a pulse signal is applied to the top electrode 21 of the capacitor 14. The potential on the bit line BL becomes the capacitor charge divided by the bit line capacitance. Since the capacitor charge is dependent upon the bi-stable polarization state of the ferroelectric core, the bit line potential can have two distinct values. A sense amplifier (not shown) is connected to the bit line BL and detects the voltage associated with a logic value of either 1 or 0. Frequently the sense amplifier reference voltage is a ferroelectric or non-ferroelectric capacitor connected to another bit line that is not being read. In this manner, the data stored in the 1T/1C cell 10 is retrieved.

A characteristic of the cell 10 is that read operations are destructive. After a read operation, the data is rewritten to restore its value. This is similar to the way a DRAM operates. A difference from a DRAM, however, is that the ferroelectric memory cell retains its state until it is interrogated, thereby eliminating the need for refresh.

Prior art FIG. 2, illustrates a 2T/2C memory cell 30. The memory cell 30 comprises two transistors 36 and 38 and two ferroelectric capacitors 40 and 42, respectively. The first transistor 36 couples between a bit line BL and the first capacitor 40. The second transistor 38 couples between a BL-bar and the second capacitor 42. The capacitors 40 and 42 are connected to a common drive line DL, to which a signal is applied for polarizing the capacitors.

In a write operation, the first and second transistors 36 and 38 of the dual capacitor ferroelectric memory cell 30 are enabled via a word line WL to couple the capacitors 40 and 42 to the complementary logic levels on the bit line BL and the bit-bar line BL-bar. The common drive line DL of the capacitors is pulsed during the write operation to polarize the dual capacitor memory cell 30 to one of two logic states.

In a read operation, the first and second transistors 36 and 38 are enabled via the word line WL to couple the information stored on the first and second capacitors 40 and 42 to the bit line BL and the bit-bar line BL-bar, respectively. A differential signal (not shown) is thus generated across the bit line BL and the bit-bar line BL-bar. A sense amplifier (not shown) senses the differential signal and determines the logic level stored in memory.

A FeRAM device can be either a stand-alone device or one that is integrated onto a semiconductor chip that includes many other device types. For example, a single chip comprising FeRAM may be a digital signal processor, a microprocessor, a smart card, or a microcontroller, each having a plurality of devices appropriate to its function.

Prior art FIG. 3 provides a fragmentary cross section of an exemplary semiconductor device comprising FeRAM and other devices. Two devices are illustrated, both of which are included in a single chip. Device 103 is a partially fabricated FeRAM. Device 105 is a high-voltage transistor, low-voltage transistor, high-speed logic transistor, I/O transistor, analog transistor, or other device.

Both devices 103 and 105 comprise gate structures 106 including a gate dielectric (comprising, for example, silicon dioxide, an oxynitride, a silicon nitride, BST, PZT, a silicate, some other high-k dielectric material, or any combination or stack thereof, a gate electrode (comprising, for example, polycrystalline silicon doped either p-type or n-type with a silicide formed on top, or a metal such as titanium, tungsten, TiN, tantalum, TaN or other type metal). The gate structures 106 further comprise side wall insulators (for example, comprising an oxide, a nitride, an oxynitride, or a combination or stack thereof). In general, the generic terms oxide, nitride and oxynitride refer to silicon oxide, silicon nitride and silicon oxy-nitride. The term “oxide” may, in general, include doped oxides as well, such as boron and/or phosphorous doped silicon oxide. Both devices 103 and 105 also comprise source/drain regions 108, which may be formed via, for example, implantation using conventional dopants and processing conditions. Lightly doped drain extensions 109 as well as pocket implants may also be utilized. The source/drain regions 108 may be silicided (for example, with titanium, cobalt, nickel, tungsten or other conventional silicide material).

Both devices 103 and 105 comprise a dielectric layer 112, which may initially be formed over the entire substrate 102 and then patterned to form openings for contacts to the source/drain regions 108 and the gate structures 106. These openings are filled with one or more conductive materials to form plugs 114 (for example, comprising a metal such as tungsten, molybdenum, titanium, titanium nitride, tantalum nitride, or a metal silicide such as Ti, Ni or Co, copper or doped polysilicon, tungsten and copper being preferred choices). A liner/barrier layer 116 is generally formed between the plug 114 and the dielectric 112. Such a liner/barrier layer 116 comprises, for example, Ti, TiN, TaSiN, Ta, TaN, TiSiN, a stack thereof, or any other conventional liner/barrier material. Preferably, the plugs 114 are formed so as to land on the silicided regions of the source/drain regions 108 and the gates 106. The dielectric layer 112 comprises, for example, SiO₂ (doped or undoped with preferable dopants such as boron or phosphorous) possibly with a layer of hydrogen or deuterium containing silicon nitride next to the gate. The dielectric layer 112 may be referred to as the field oxide.

The dielectric layer 112, the diffusion barrier 116, and the plug 114 are the interconnect layer 115. The interconnect layer 115 may be referred to as the contact level for FeRAM devices, which are formed on top of it. The interconnect layer 115 is generally planarized either as part of its formation process or for improved lithography of overlying layers. The planarization process typically comprises chemical mechanical polishing (CMP). CMP generally leaves small metal particles on the upper surface of the interconnect layer 115. The upper surface of the interconnect layer 115 is generally treated with a plasma etch to remove these particles.

Plugs 136 and 150 and conductors 144 and 164 comprise a metal material (for example, copper, aluminum, or tungsten). A barrier/liner may be formed between the plugs 136 and 150 and the respective interlevel dielectric layers 112, 134, and 160. Optional barrier/liner layers are layers 138 and 148 and liners 142, 146, 162 and 166. The interlayer dielectric and plug materials should be compatible with an FeRAM thermal budget. With existing technology (i.e., one that incorporates W plugs and a SiO₂ interlevel dielectric layer), the FeRAM thermal budget should be less than approximately 600 or 650 C. If the interlevel dielectric layer includes a low dielectric constant (“low K”) layer, the FeRAM thermal budget may need to be reduced further. The preferred interlayer dielectric 112 is therefore a material that can withstand a thermal budget in excess of 600 C, such as silicon oxide (doped and/or undoped), silicon nitride, and/or silicon oxy-nitride.

Aluminum metallization is formed, for example, by etching and copper metallization is preferably formed by a damascene process, although either process is possible for either metal. Aluminum metallization preferably includes CVD tungsten or aluminum plugs. Diffusion barriers for Al may include, for example, TiN and/or Ti. Copper metallization may have, for example, copper or tungsten plugs. Diffusion barriers for Cu or tungsten may include, for example, Ti, TiN, TiSiN, Ta, TaN, and/or TaSiN, with TiN being preferred.

Level 127 is added so as to accommodate the FeRAM cells. In particular, level 127 enables FeRAM devices with a capacitor under bit line configuration compatible with a high-density memory. However, if planarity is not a necessity, the layer 127 can be excluded.

Thin dielectric layers (not shown) may be formed between each of the interlevel dielectric layers 112, 134 and 160. If formed, these thin dielectric layers may comprise, for example, silicon nitride, silicon carbide, SiCNO or a silicon oxide (for example, a high-density plasma oxide). Interlevel dielectric layers 112, 134, and 160 may comprise, for example, an oxide, FSG, PSG, BPSG, PETEOS, HDP oxide, a silicon nitride, silicon oxynitride, silicon carbide, silicon carbo-oxy-nitride, a low dielectric constant material (for example, SiLK, porous SiLK, teflon, low-K polymer (possibly porous), aerogel, xerogel, black diamond, HSQ, or any other porous glass material), or a combination or stack thereof.

The FeRAM capacitor 125, which comprises several layers, resides above the interconnect layer 115. The FeRAM capacitor 125 includes a bottom diffusion barrier layer 122, a bottom electrode layer 124, a ferroelectric dielectric layer 126, a top electrode 128, and a hard mask layer 130. The diffusion barrier layer 122 is conductive. The hard mask layer 130 is used in the capacitor stack etch. After the etch, the capacitor stack 125 is covered by a diffusion barrier layer 132.

An exemplary method 200 of forming a FeRAM capacitor is illustrated by prior art FIG. 4. At 202, the interlevel dielectric 112 (e.g., SiO₂), the barrier layer 116 (e.g., TiN), and the plugs 114 (e.g., W) are formed. The FeRAM capacitor is formed on the upper surface of the resulting interconnect layer 115.

At 204, the bottom electrode diffusion barrier layer 122 is formed. The bottom electrode layer 124 can be formed directly over the interconnect layer 115, however, the bottom electrode material, for example, an iridium or an iridium/iridium oxide multi-layer combination may hot provide a sufficient diffusion barrier for subsequent processing. During subsequent formation of the ferroelectric dielectric 126, for example, oxygen may diffuse through the bottom electrode layer 124 and cause tungsten in the plugs 114 to oxidize, thus increasing a resistance between the source/drain regions 108 and the FeRAM capacitor 125. One solution to this problem is to increase the thickness of the bottom electrode 124. This solution increases the thickness of the FeRAM capacitor 125, which preferably is as thin as possible.

The exemplary method 200 uses another solution: providing a dedicated bottom electrode diffusion barrier layer 122. The barrier layer 122 is formed over the interlayer dielectric 112 and the tungsten contact 114 prior to the formation of the bottom electrode 124. The barrier layer 122 is electrically conductive and serves to provide an effective diffusion barrier without increasing the thickness of the bottom electrode 124. Since the diffusion barrier 122 is a more efficient barrier than the bottom electrode material(s), even though an additional layer is employed, the resulting thickness of the capacitor stack is less than would be required if the bottom electrode material was increased to provide equivalent diffusion barrier performance. A typical diffusion barrier material is TiAlN formed via physical vapor deposition.

In another application assigned to the inventors' employers, the desirability to a TiAlON diffusion barrier layer is described to prevent undercutting of the capacitor stack during the stack etch. The amount of oxygen is tailored to mitigate the undercutting while not excessively increasing the resistance of the diffusion barrier layer 122. An additional TiN layer beneath the TiAlON layer is also suggested for the purpose of filling seams in the plugs 114 left by chemical-mechanical polishing. Other diffusion barrier layer materials may be employed, for example, TaSiN, TiSiN, TaAlN, Ti, TiN, Ta, TaN, HfN, ZrN, HfAlN, CrN, TaAlN, CrAlN. The interconnect layer is preferably cleaned prior to deposition of the interlayer dielectric 112. One option for cleaning this layer is sputter cleaning with Ar

At 206, the bottom electrode layer 124 is formed. Typically, the bottom electrode 124 is around 30-100 nm thick, is stable in oxygen and is comprised of a noble metal or conductive oxide such as iridium, iridium oxide, Pt, Pd, PdOx, Au, Ru, RuOₓ, Rh, RhOₓ, LaSrCoO₃, (Ba,Sr)RuO₃, LaNiO₃ or any stack or combination thereof.

For a PZT dielectric 126, it is preferred to have oxide electrode materials such as IrOx in contact with the dielectric. On the other hand, it is preferred to have a noble metal in contact with the lower diffusion barrier layer 122 and the hard mask 132. Unlike an oxide, a noble metal will not oxidize the diffusion barrier layer 122 and result in the formation of an insulating layer that increases contact resistance. Accordingly, it is preferred that the upper and lower electrodes each comprise multiple layers, including at least an metal and a metal oxide, such as Ir and IrO₂, with the metal in contact with the dielectric 126. A preferred bottom electrode for a PZT dielectric 126 comprises IrOx in a layer about 10-40 nm thick and Ir in a layer about 20-30 nm. The layers can be formed be deposited by sputter deposition with (Ar) for Ir and reactive sputter deposition with (Ar+O₂) for IrOx.

At 208, the ferroelectric dielectric 126 is formed on the bottom electrode 124. Preferably, the ferroelectric dielectric 126 is less than about 150 nm thick (more preferably less than about 100 nm thick and still more preferably less than about 50 nm thick) and is comprised of a ferroelectric material such as Pb(Zr,Ti)O₃ PZT (lead zirconate titanate), doped PZT with donors (Nb, La, Ta) acceptors (Mn, Co, Fe, Ni, Al) and/or both, PZT doped and alloyed with SrTiO3, BaTiO3 or CaTiO3, strontium bismuth tantalate (SBT) and other layered perovskites such as strontium bismuth niobate tantalate (SBNT) or bismuth titanate, BaTiO3, PbTiO3, Bi2TiO3 etc. PZT is a desirable choice for the capacitor dielectric because it has the highest polarization and the lowest processing temperature of the aforementioned materials. Thin PZT (<100 nm) is particularly advantageous in making integration simpler (less material to etch) and less expensive (less material to deposit therefore less precursor). Because PZT has the largest switched polarization, it is also possible to minimize capacitor area using such material.

A preferred deposition technique for these dielectrics is metal organic chemical vapor deposition (MOCVD). MOCVD is preferred especially for thin films (<100 nm). MOCVD also permits the film thickness to be scaled without significant degradation of switched polarization and coercive field, yielding PZT films with a low operating voltage and large polarization values. In addition, the reliability of the MOCVD PZT film is better than that generally obtained using other deposition techniques, particularly with respect to imprint/retention.

At 210, the top electrode 128 comprising two layers is formed over the ferroelectric dielectric 126. While two layers are suggested, the top electrode can be just one layer. Preferably, the layer next to the a PZT ferroelectric dielectric layer 126 comprises iridium oxide (preferably less than about 100 nm thick, more preferably less than about 50 nm thick, and still more preferably less than about 30 nm thick). Preferably, the layer between the conductive oxide and top electrode diffusion barrier/hard mask comprises iridium (preferably less than about 100 nm thick, more preferably less than about 50 nm thick and even more preferably less than about 20 nm thick).

In general, it is advantageous for Pb based ferroelectrics to have a conductive oxide such as IrOₓ, RuOₓ, RhOₓ, PdOₓ, PtOₓ, AgOₓ, (Ba,Sr)RuO₃, LaSrCoO₃, LaNiO₃, YBa₂Cu₃O₇₋ₓ in the top electrode in order to minimize degradation caused by many opposite state write/read operations (fatigue). On the other hand, many Bi ferroelectrics such as SBT can retain good fatigue characteristics with a top electrode comprising only noble metals.

If the top electrode 128 comprises an oxide layer, it is advantageous to have a noble metal layer above it in order to maintain low contact resistance with the top metal contact 136. For example, it is possible that TiN in contact with IrOx might form an insulating material, TiO₂, during subsequent thermal processing. For any electrode using an expensive noble metal such as Pt, Ru, Pd, or Ir it is advantageous from a cost and integration standpoint to use as thin of layer as possible.

Preferably, the entire capacitor stack is patterned and etched at one time. For this purpose, a hard mask layer 130 is formed over the stack at 212. The hard mask layer 130 preferably functions as an etch stop during formation of vias through the dielectric 134. The hard mask 130 preferable also functions during back end processing to protect the capacitor stack from hydrogen and deuterium, which are used in processes such as CVD deposition of SiO₂, Si₃N₄, and tungsten, SiO₂ via etching, and annealing.

The hard mask 130 may comprise a single layer of material, typically a TiN layer or a TiAlN layer. If the bottom electrode diffusion barrier layer 122 is composed of the same material, a substantial portion of the hard mask 130 will be removed during the etch of the bottom electrode diffusion barrier layer 122. The initial thickness of the hard mask 130 is therefore preferably great enough that a functional thickness remains after a part of it is removed during the capacitor stack etch. An exemplary thickness for the hard mask 130, which may include multiple layers, is from about 50 to about 500 nm thick (more preferably from about 100 to about 300 nm thick, and still more preferably about 200 nm thick).

Forming devices with FeRAM presents several challenges. As explained above, the ferroelectric capacitor alone requires many separate layers. There is a need to limit the number and complexity of processing steps used to form these layers and the devices in general. In addition, FeRAM devices must not be excessively degraded by back end processing and their manufacture must be integrated into existing back end process flows with minimal modification to those process flows. This is a significant challenge since ferroelectric capacitors have been shown to be sensitive to hydrogen degradation and most back end process flows use hydrogen/deuterium at many stages (SiO₂, Si₃N₄, and CVD W deposition, SiO₂ via etch, and forming gas anneals). Degradation can reduce the yield of functional devices thus increasing the cost per functional device. Degradation can also reduce the performance reliability of generally functional FeRAM devices. In view of these challenges, there has been a long felt need for improved FeRAM and FeRAM manufacturing processes.

### SUMMARY

One of the inventors' concepts relates to a semiconductor manufacturing process in which a ferroelectric capacitor stack is formed over a metal-dielectric interconnect layer. After forming the interconnect layer, the surface of the interconnect layer is treated with gas cluster ion beam (GCIB) processing. Prior to this processing, the surface typically includes metal recesses. The GCIB processing smoothes these recesses and provides a more level surface on which to form the ferroelectric capacitor stack. When the ferroelectric capacitor stack is formed on this leveled surface, leakage is reduced and yields increase as compared to the case where GCIB processing is not used.

Another of the inventors' concepts relates to a method of forming FeRAM. The method comprises forming a transistor in a semiconductor substrate; forming an interconnect layer over the transistor; treating the upper surface of the interconnect layer using a gas-cluster ion beam; forming a bottom electrode layer over the interconnect layer; forming a ferroelectric dielectric layer and a top electrode layer over the bottom electrode layer, forming a hard mask layer over top electrode layer, patterning the hard mask; and selectively etching the top electrode layer, the ferroelectric dielectric layer, and the bottom electrode layer to define a capacitor stack using the hard mask.

The primary purpose of this summary has been to present certain of the inventors' concepts in a simplified form to facilitate understanding of the more detailed description that follows. This summary is not a comprehensive description of every one of the inventors concepts or every combination of the inventors concepts that can be considered “invention”. Other concepts of the inventors will be conveyed to one of ordinary skill in the art by the following detailed description together with the drawings. The specifics disclosed herein may be generalized, narrowed, and combined in various ways with the ultimate statement of what the inventors claim as their invention being reserved for the claims that follow.

### BRIEF DESCRIPTION OF THE DRAWINGS

FIG. 1 is a prior art schematic diagram illustrating an exemplary 1T/1C FeRAM memory cell;

FIG. 2 is a prior schematic diagram illustrating an exemplary 2T/2C FeRAM memory cell;

FIG. 3 is a fragmentary cross-sectional view of a prior art partially fabricated device containing FeRAM capacitors and other devices.

FIG. 4 is flow chart of an exemplary prior art method of forming the device of FIG. 3

FIG. 5 is a cross sectional view of a partially fabricated FeRAM device taken with a scanning electron microscope.

FIG. 6 is a top-down view of a partially fabricated FeRAM device taken with a scanning electron microscope.

FIG. 7 is an image of the contact layer of a partially fabricated semi-conductor device taken with an atomic force microscope.

FIG. 8 is an image of the contact layer of a partially fabricated semi-conductor device taken with an electron microscope.

FIG. 9 show electron microscope images of FeRAM capacitor stacks overlying the edge of a tungsten plug. The device on the left was fabricated without GCIB smoothing of the contact level. The device on the right was fabricated with GCIB smoothing of the contact level.

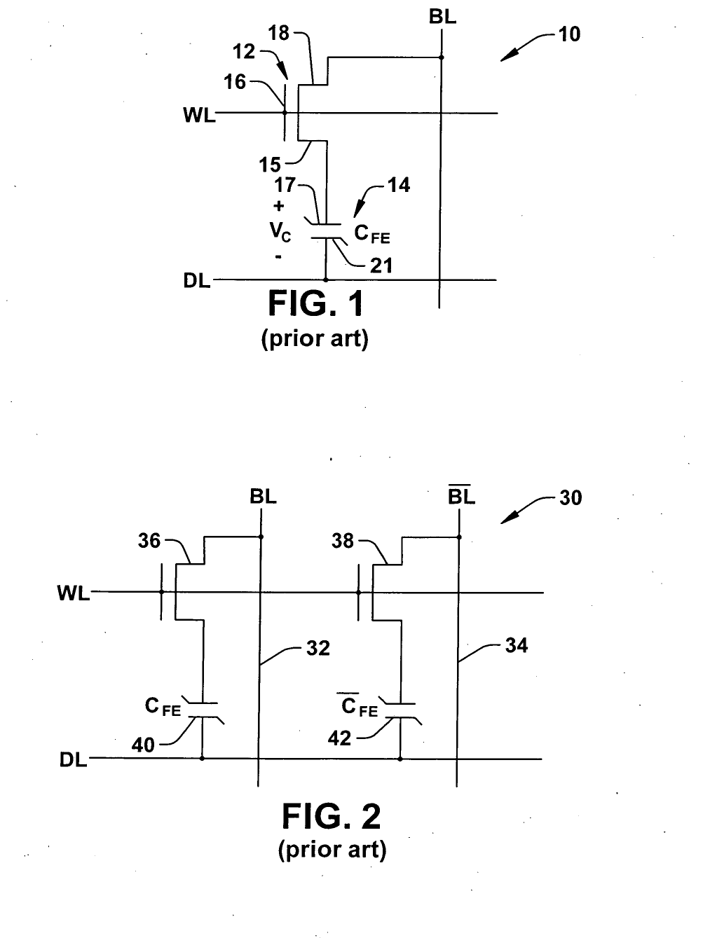

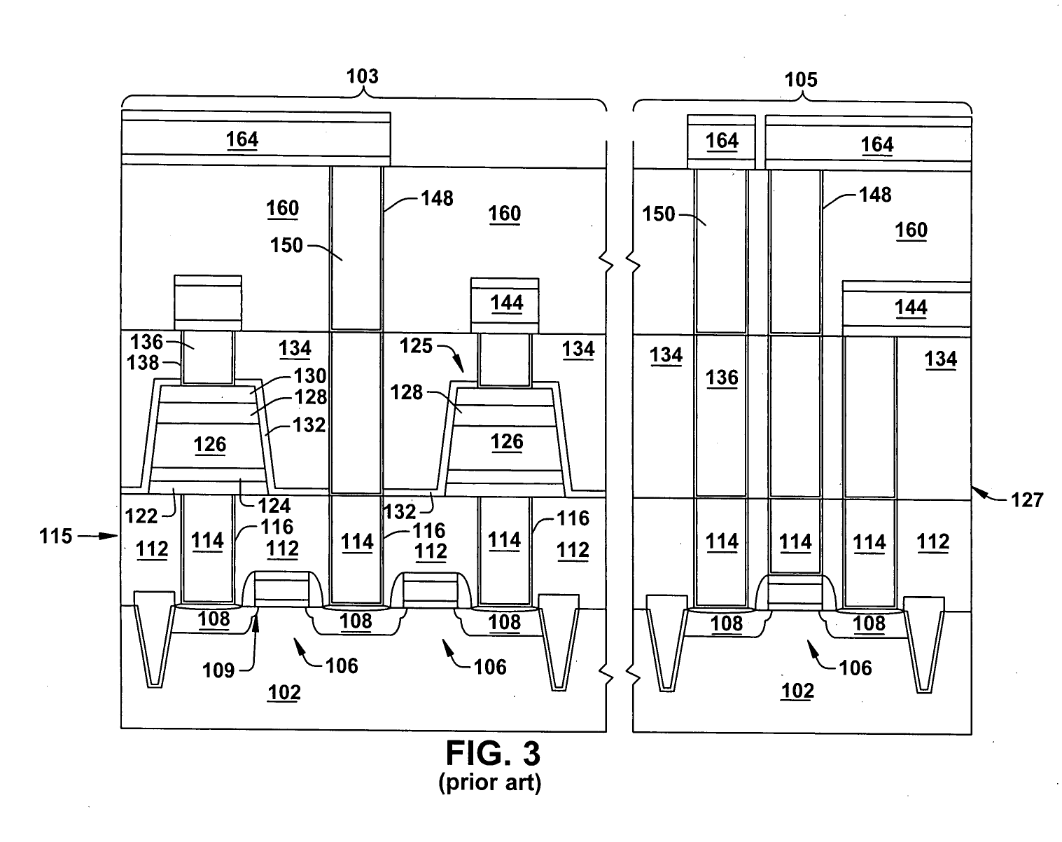

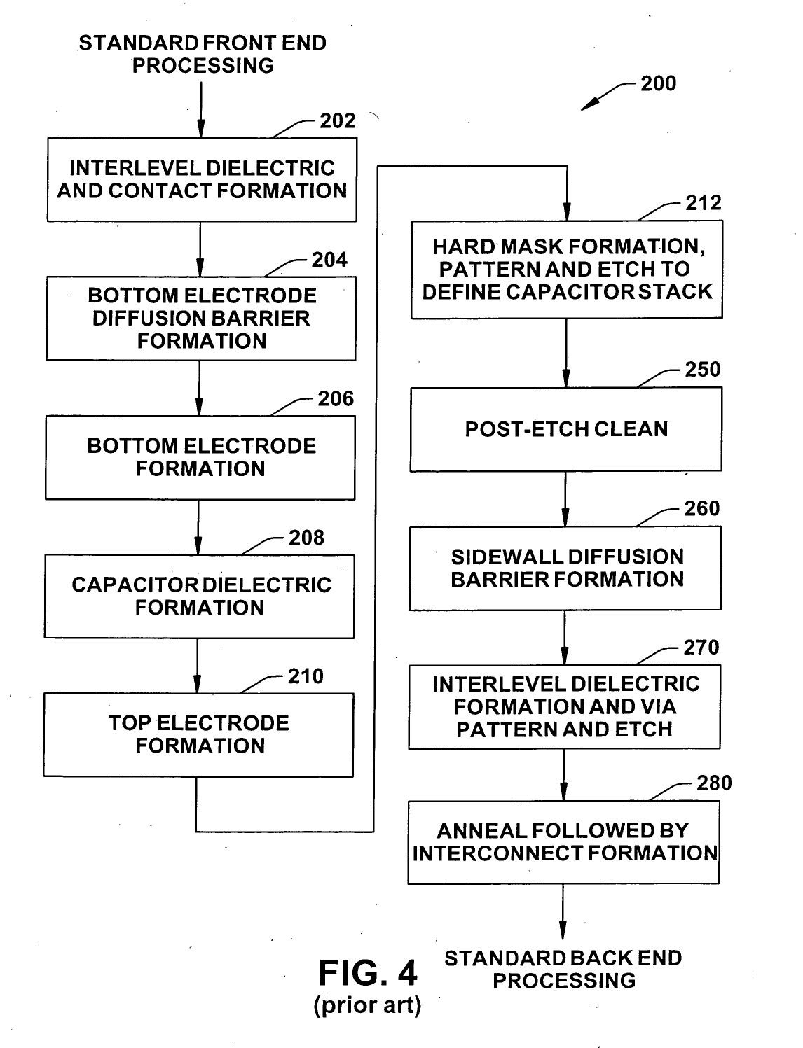

### DETAILED DESCRIPTION

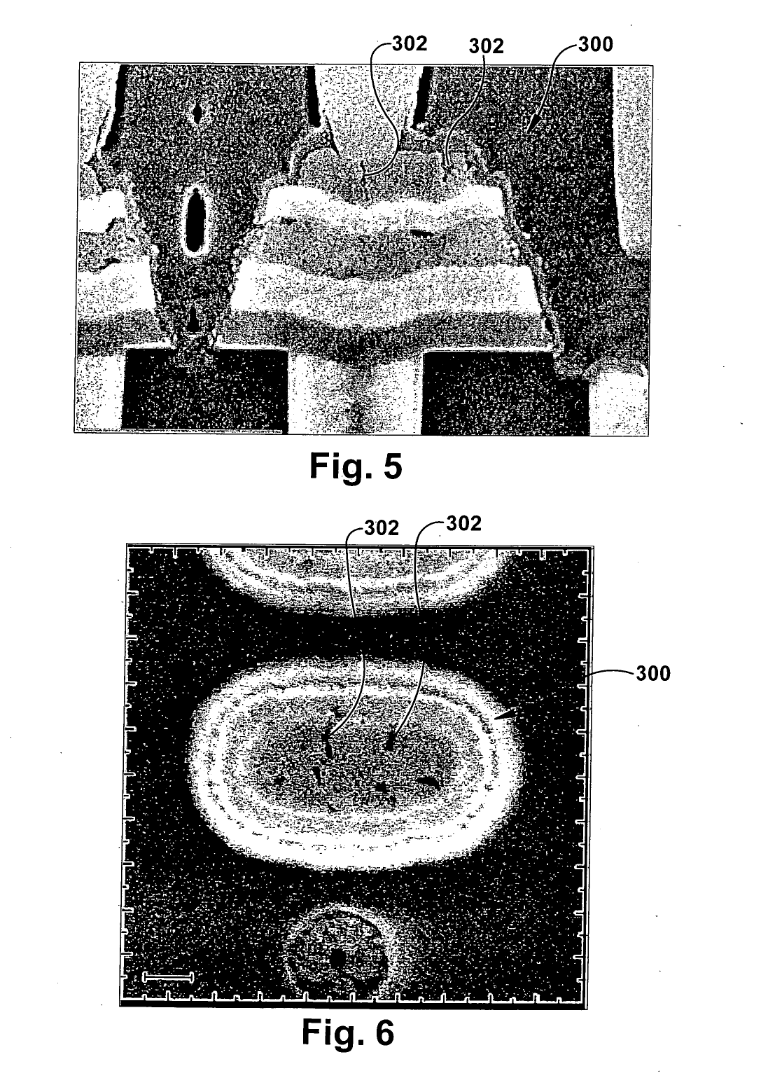

FIGS. 5 and 6 are cross-sectional and top-down SEM images of a fabricated FeRAM capacitor stack 300. The hard mask/diffusion barrier layer exhibits cracks 302. Hydrogen may diffuse through these cracks during back end processing leading to capacitor leakage and reduced yields.

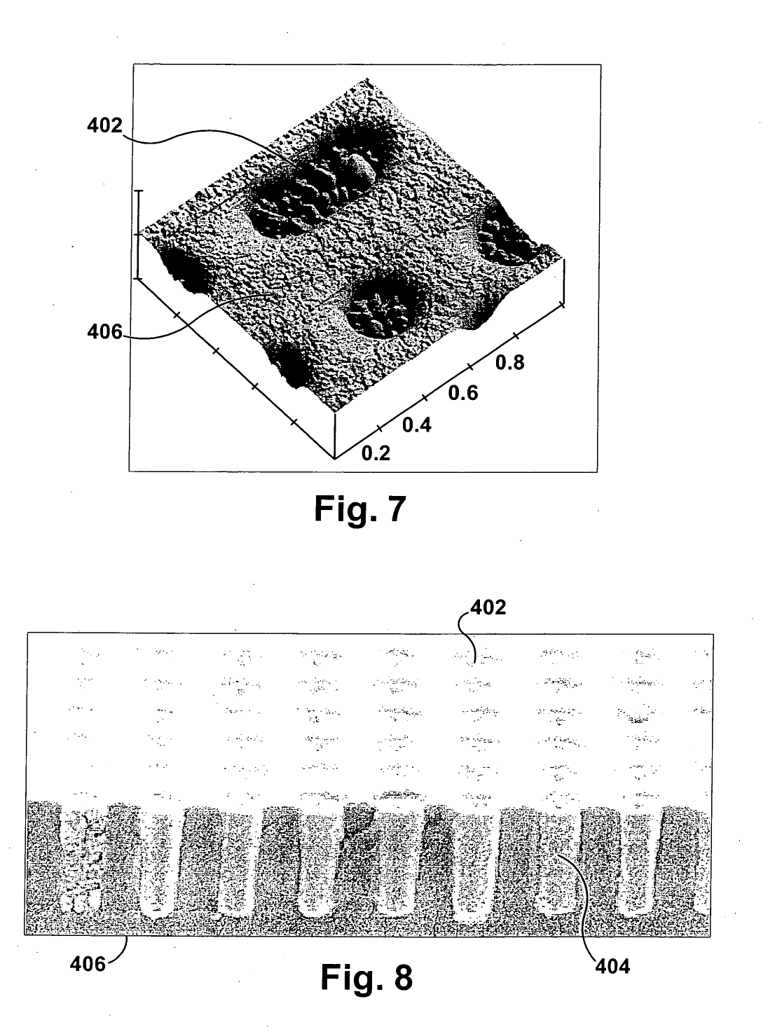

FIGS. 7 and 8 are AFM and SEM images, respectively, showing recesses 402 in tungsten plugs 404 at the upper surface of dielectic layer 406 immediately prior to capacitor stack deposition. These recesses are typically from about 100 to about 200 Angstroms deep. The inventors have concluded that the cracks 302 illustrated in FIGS. 5 and 6 form during the via etch for plugs 136 as a result of the morphology of the recessed surface of the interconnect layer 115 translated through the capacitor stack 125 to the hard mask 130. Grain boundaries in the hard mask 130 and PZT roughness also contribute to crack formation.

The inventors have also concluded that recesses in the interconnect layer 115 contribute to problems with sidewall coverage of the capacitor stack 125 by the diffusion barrier 132. The recesses in the plugs 114 create an irregular side wall surface for the capacitor stacks 125. A diffusion barrier 132, such as an Al₂O₃ barrier for example, which is intended to protect the capacitor 125 from hydrogen during back end processing, has reduced functionality due to these irregularities.

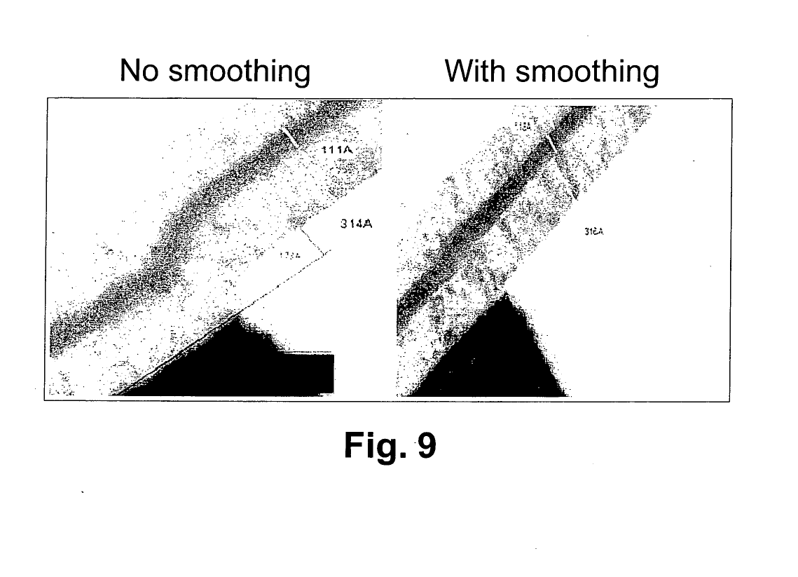

One of the inventors' concepts is to reduce the tungsten recesses 402 by GCIB smoothing of the interconnect layer 115. FIG. 9 shows the height difference at the edge of a tungsten plug 114 before and after GCIB smoothing. The tungsten recesses 402 are substantially ameliorated by the GCIB processing. This smoothing reduces hard mask and sidewall barrier defects, which increases FeRAM manufacturing yield and reduces leakage in the resulting memory devices.

GCIB is a process in which a surface is bombarded with relatively large ion clusters, e.g., from about 5,000 to about 50,000 atoms each. The clusters are accelerated to from about 1 to about 30 keV. The resulting energy per atom is typically less than about 10 eV, preferably 1 eV or less. Due to the large cluster size and low velocity in comparison to other plasma etch processes, the clusters impart their energy within a shallow region of the surface and have a low scattering cross-section (large area of impact), which results in a smoothing of the surface.

An appropriate GCIB process for the inventors' purposes has a high removal rate for the dielectric 112 in comparison to the plug material 114 and any diffusion barrier 116. The process also preferably avoids increasing the resistance of the plugs 114, by avoiding oxidation of tungsten, for example. Further, the process also preferably minimizes roughening of the dielectric 112.

In GCIB processing, a beam is scanned over the surface. The extent of material removal depends on the scan rate, the beam chemistry, and the beam energy. One or more of these parameters can vary over the surface to vary the degree of material removal from point to point.

Another of the inventors' concepts is to vary a GCIB process condition in response to a surface condition as the beam is scanned. For example, it has been found that the depth of tungsten recesses often varies over the surface of a wafer. Accordingly, the beam energy can be increased near where the recessed are deeper in order to obtain the required degree of smoothing. Rather than altering the beam energy, the scan rate or the chemistry can be varied.

Where the plugs 114 are tungsten and the sleeve or liner 116 is TiN, appropriate beam chemistries can be, for example, Ar, Ar/O₂, fluorine containing species such as CH₂F₂ , and CF₄/Ar. If oxygen containing species are used, they are preferably used in small quantities to prevent oxidation of the tungsten. Preferred chemistries are Ar and CxFyHz, wherein x≧0, y≧1, and z≧0

In one embodiment, the surface of a wafer is uniformly scanned with a gas cluster ion beam. The surface is effectively smoothed due to the selectivity of the ion beam among the surface materials and due to the physical characteristics of the beam, which tends to smooth surfaces regardless of the compositions of the surface structures.

In another embodiment, the surface is mapped for a parameter such composition or average recess depth. Based on the map, the surface is scanned with varying beam intensity, the variation being in relation to the mapped parameter. Instead of a map, a surface parameter can be detected as the gas cluster ion beam is scanned and the intensity of the beam (or other GCIB process parameter) varied based on the detected parameter.

In a further embodiment, the surface is mapped for a parameter such as composition or average recess depth and the surface is scanned with gas cluster ion beams two or more times, each time with a different chemistry. During each scan, the beam intensity can be varied over the surface, the beam shut on and off, or the beam's movement rate varied in relation to the mapped parameter. In this manner, a different chemistry can be used to etch the sleeve 116 than is used to etch the dielectric 112. In another example, a first scan is used to level the surface and a second scan is used to smooth the field oxide. Again, rather than mapping the surface in advance, a surface condition can be detected as the scan is progressing.

GCIB smoothing reduces the average height difference between the plugs 114 and the dielectric 112. Typically, this height difference is initially at least about 100 Angstroms. Preferably, this difference reduced to less than about 50 Angstroms, more preferably to less than about 30 Angstroms, and still more preferable to less than about 15 Angstroms.

Additional smoothing may be desired after initial GCIB processing of the interconnect layer 115. GCIB is not generally used, as here, to remove large amounts of material. Removing large amounts of material may result in roughening of the surface of the dielectric 112 even as the overall contact layer is smoothed on a larger measurement scale. One approach, suggested above, is a second GCIB process scan with conditions tailored to smoothing the dielectric.

A further of the inventors' concepts is, following GCIB smoothing of the contact layer, to perform GCIB smoothing of another layer above the contact layer. In one embodiment, the bottom electrode layer 124 is smoothed by GCIB. In another embodiment, the PZT layer 126 is smoothed by GCIB. Chemistries for these additional GCIB processing steps can be, for example, Ar/O₂, N2, or CF4/O₂.

The invention as delineated by the following claims has been shown and/or described in terms of certain concepts, components, and features. A particular component or feature may have been disclosed herein with respect to only one of several concepts or examples, and may have been described both broadly and narrowly. Different components or features in their broad or narrow conceptions may be combined with other components or features in their broad or narrow conceptions where such combinations would be recognized as logical by one of ordinary skill in the art. Also, this one specification may describe more than one invention and the following claims do not necessarily encompass every concept, aspect, embodiment, or example described herein.

The claims are:

1. A method of forming a FeRAM, comprising:
forming a transistor on a semiconductor substrate;
forming an interconnect layer over the transistor, the interconnect layer comprising an upper surface and a contact plug extending down to the underlying transistor;
treating the upper surface of the interconnect layer and contact plug using a gas cluster ion beam;
forming a bottom electrode layer, a ferroelectric dielectric layer, and a top electrode layer over the treated upper surface;
forming a hard mask layer over top electrode layer;
patterning the hard mask; and
selectively etching the top electrode layer, the ferroelectric dielectric layer, and the bottom electrode layer to define a capacitor stack using the hard mask.

2. The method of claim 1, further comprising forming a diffusion barrier layer over the upper surface after treatment with the gas cluster ion beam and before depositing the bottom electrode layer.

3. The method of claim 1, wherein treating the upper surface with the gas cluster ion beam comprises scanning over the surface of the interconnect layer with at least one gas cluster ion beam parameter that varies over the surface in response to non-uniformities thereon.

4. The method of claim 3, wherein the non-uniformities are variations in depth of plug recesses.

5. The method of claim 1, wherein treating the upper surfaces substantially reduces a depth of a plug recess in the contact plug.

6. The method of claim 5, wherein the recess resulted from a prior step of chemical-mechanical polishing.

7. The method of claim 1, wherein the gas cluster ion beam comprises clusters of at least about 1,000 atoms.

8. The method of claim 7, wherein the clusters consist essentially of atoms selected from the group consisting of Ar, O₂, and CxFyHz, wherein x≧0, y≧1, and z≧0.

9. The method of claim 1, wherein the energy of the gas cluster ion beam is less than about 10 eV per atom.

10. The method of claim 1, further comprising GCIB smoothing of one of the layers above the interconnect layer using a treating thereof using the gas cluster ion beam.

11. A process of forming a ferroelectric capacitor stack over an interconnect layer comprising a dielectic with conductive plugs extending therethrough, comprising:
smoothing a surface of the interconnect layer using gas cluster ion beam processing; and
forming the ferroelectric capacitor stack over the smoothed surface.

12. The process of claim 11, wherein gas cluster ion beam processing comprises rastering a gas cluster ion beam over the surface of the interconnect layer with conditions that vary over the surface in response to non-uniformities in the surface.

13. The process of claim 11, further comprising smoothing a layer of the ferroelectric capacitor stack using gas cluster ion beam processing.

14. The process of claim 12, wherein the non-uniformities are variations in plug recess.

15. The method of claim 14, wherein the smoothing substantially reduces the depths of plug recesses in the interconnect layer.

16. The method of claim 15, wherein the smoothing reduces an average depth of the plug recesses from greater than about 100 Angstroms to less than about 50 Angstroms.

17. The method of claim 15, wherein the recesses resulted from a prior step of chemical-mechanical polishing.

18. The method of claim 11, wherein gas cluster ion beam processing comprises the use of ion clusters consisting essentially of atoms selected from the group consisting of Ar, O₂, and CxFyHz, wherein x≧0, y≧1, and z≧0.

19. The method of claim 11, wherein gas cluster ion beam processing comprises scanning the surface of the interconnect layer, with at least one GCIB process parameter varying over the surface in response to a variations in a surface condition.

20. The method of claim 11, wherein gas cluster ion beam processing comprises scanning the surface of the interconnect layer in multiple steps, with at least one GCIB process parameter varied from one step to a next step.

21. The method of claim 11, wherein a surface condition being smoothed is plug recess depth.
